(19) United States
(12) Patent Application Publication
(10) Pub. No.: US 2026/0090342 A1
(43) Pub. Date: Mar. 26, 2026

(54) METHODS OF FORMING PATTERNED STRUCTURE

(71) Applicant: NANYA TECHNOLOGY CORPORATION, New Taipei City (TW)

(72) Inventor: Chao Yuan CHENG, New Taipei City (TW)

(21) Appl. No.: 18/893,999

(22) Filed: Sep. 24, 2024

(51) Int. Cl. H01L 21/027; H01L 21/033; H01L 21/311

(52) U.S. Cl. CPC H10P 76/2041; H10P 50/73; H10P 76/405; H10P 76/4083; H10P 76/4085

(57) ABSTRACT

The present disclosure provides a method of forming a patterned structure. The method includes the following operations. A photoresist layer on a target layer is patterned to form a first opening in a patterned photoresist layer. A directed self-assembly layer is formed on the patterned photoresist layer and in the first opening, in which a directed self-assembly material in the directed self-assembly layer separates into a first phase on the patterned photoresist layer and a second phase in the first opening by the first phase being attracted by a polarity of the patterned photoresist layer. The second phase is removed to form a second opening through the directed self-assembly layer. The target layer is etched through the second opening.

### BACKGROUND

### Field of Invention

The present disclosure relates to methods of forming patterned structure.

### Description of Related Art

The photoresist is used in the semiconductor process to form the pattern. As the size of the semiconductor structure is manufactured smaller and smaller, the pattern with a larger aspect ratio is more desirable to improve performance and increase productivity. The thicker photoresist may be useful in forming the pattern with the larger aspect ratio. However, the light used to pattern the photoresist may form a standing wave in the photoresist, especially when the photoresist is too thick. The standing wave of the light may cause the pattern formed in the photoresist to deviate from the expectation, for example, increasing the roughness of the pattern, causing footing or undercut in the pattern, and so on. Once the pattern formed in the photoresist is not expected, the pattern formed in the target layer by using the patterned photoresist also deviates from the expectation. Therefore, it is necessary to develop a novel method to pattern the structure.

### SUMMARY

The present disclosure provides a method of forming a patterned structure. The method includes the following operations. A photoresist layer on a target layer is patterned to form a first opening in a patterned photoresist layer. A directed self-assembly layer is formed on the patterned photoresist layer and in the first opening, in which a directed self-assembly material in the directed self-assembly layer separates into a first phase on the patterned photoresist layer and a second phase in the first opening by the first phase being attracted by a polarity of the patterned photoresist layer. The second phase is removed to form a second opening through the directed self-assembly layer. The target layer is etched through the second opening.

In some embodiments, a thickness of the photoresist layer is from 80 nm to 120 nm.

In some embodiments, when forming the directed self-assembly layer on the patterned photoresist layer, a total thickness of the patterned photoresist layer and a portion of the directed self-assembly layer on the patterned photoresist layer is from 120 nm to 300 nm.

In some embodiments, when forming the directed self-assembly layer on the patterned photoresist layer, a thickness of a portion of the directed self-assembly layer on the patterned photoresist layer is from 10 nm to 180 nm.

In some embodiments, the patterned photoresist layer is polar to attract a polar end of the first phase, or the patterned photoresist layer is nonpolar to attract a nonpolar end of the first phase.

In some embodiments, the directed self-assembly material includes a first moiety having a first glass transition temperature and a second moiety having a second glass transition temperature smaller than the first glass transition temperature, and the first moiety is attached to the patterned photoresist layer when the directed self-assembly material separates into the first phase and the second phase.

In some embodiments, the directed self-assembly layer is formed at a temperature between the first glass transition temperature and the second glass transition temperature.

In some embodiments, the directed self-assembly material is a copolymer, and the copolymer aligns vertically on a surface of the patterned photoresist layer.

In some embodiments, the first phase further includes a portion extending to cover a side surface of the patterned photoresist layer.

In some embodiments, the method further includes forming a hard mask layer on the target layer and forming the photoresist layer on the hard mask layer before patterning the photoresist layer.

The present disclosure also provides a method of forming a patterned structure. The method includes the following operations. A photoresist layer on a target layer is patterned to form a first opening in a patterned photoresist layer. A directed self-assembly layer is formed on the patterned photoresist layer and in the first opening, in which a directed self-assembly material in the directed self-assembly layer separates into a first phase and a second phase by the first phase being attracted by a water affinity of the patterned photoresist layer, the first phase covers a top surface of the patterned photoresist layer and a side surface of the first opening, and the second phase is surrounded by the first phase. The second phase is removed to form a second opening through the directed self-assembly layer. The target layer is etched through the second opening.

In some embodiments, a thickness of the photoresist layer is from 80 nm to 120 nm.

In some embodiments, when forming the directed self-assembly layer on the patterned photoresist layer, a total thickness of the patterned photoresist layer and a portion of the directed self-assembly layer on the patterned photoresist layer is from 120 nm to 300 nm.

In some embodiments, when forming the directed self-assembly layer on the patterned photoresist layer, a thickness of a portion of the directed self-assembly layer on the patterned photoresist layer is from 10 nm to 180 nm.

In some embodiments, the patterned photoresist layer is hydrophilic to attract a hydrophilic end of the first phase, or the patterned photoresist layer is hydrophobic to attract a hydrophobic end of the first phase.

In some embodiments, the directed self-assembly material includes a first moiety having a first glass transition temperature and a second moiety having a second glass transition temperature smaller than the first glass transition temperature, and the first moiety is attached to the patterned photoresist layer when the directed self-assembly material separates into the first phase and the second phase.

In some embodiments, the directed self-assembly layer is formed at a temperature between the first glass transition temperature and the second glass transition temperature.

In some embodiments, the directed self-assembly material is a copolymer, and the copolymer aligns vertically on the top surface of the patterned photoresist layer.

In some embodiments, the method further includes forming a hard mask layer on the target layer and forming the photoresist layer on the hard mask layer before patterning the photoresist layer.

### BRIEF DESCRIPTION OF THE DRAWINGS

The present disclosure can be more fully understood by reading the following detailed description of the embodiments, with reference made to the accompanying figures as follows.

FIGS. 1 and 2 are flow charts of methods of forming patterned structures according to some embodiments of the present disclosure.

FIGS. 3 to 8 are cross-sectional views of the structures in the stages of forming the patterned structures according to some embodiments of the present disclosure.

### DETAILED DESCRIPTION

To make the description of the present disclosure detailed and complete, the following is an illustrative description of the aspects of the embodiments. This is not to limit the embodiments of the present disclosure to only one form. The embodiments of the present disclosure may be combined or substituted with each other when it is beneficial, and other embodiments may be added without further explanation.

In addition, spatially relative terms, such as below and above, etc., may be used in the present disclosure to describe the relationship between one element (or feature) to another element (or feature) in the figures. In addition to the orientation depicted in the figures, spatially relative terms are intended to encompass different orientations of the device in use or in operation. For example, the device may be oriented otherwise (e.g., rotated at 90 degrees), and the spatially relative terms can be interpreted accordingly. In the present disclosure, unless otherwise indicated, the same element numbers in different figures refer to the same or similar elements formed from the same or similar materials by the same or similar methods.

The terms “around”, “approximately”, “nearly”, “basically”, “substantially”, etc., used in the present disclosure include the stated values (or characteristics) and a deviation of the stated values (or characteristics) understood by one skilled in the art. For example, considering the errors of the values (or characteristics), these terms may indicate the values within one or more standard deviations (e.g., the values within ±30%, ±20%, ±15%, ±10%, or ±5%), or may indicate the characteristics including the deviation from the practical operation (e.g., the “substantially parallel” may indicate close to parallel in practical, rather than a perfect ideally parallelism). Furthermore, it is possible to select an acceptable range of the deviation according to the nature of the measurement or other properties, instead of applying only one single deviation range to all the values (or characteristics).

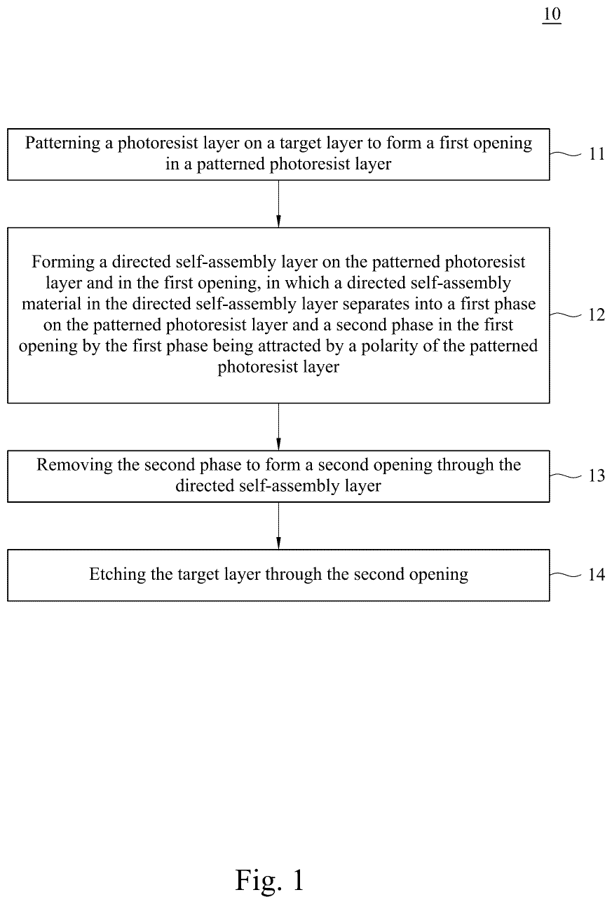

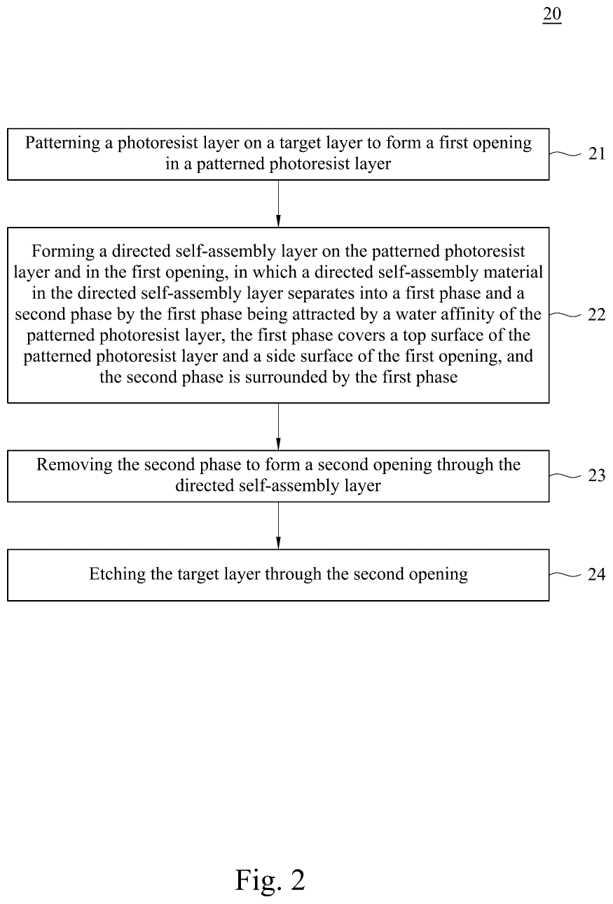

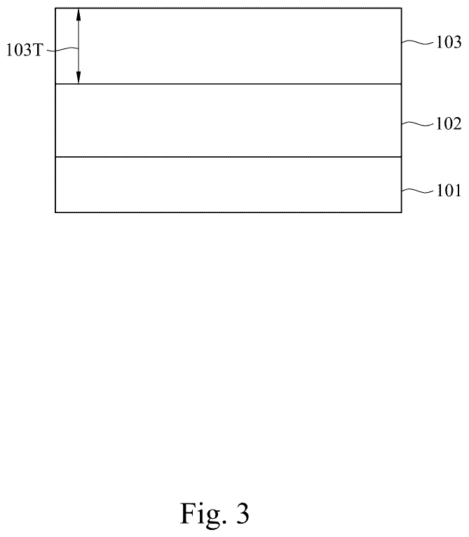

The present disclosure provides a method 10 of forming a patterned structure and a method 20 of forming a patterned structure, as shown in FIGS. 1 and 2. When reading FIGS. 1 and 2, please also refer to FIGS. 3 to 8 for more detail on the present disclosure. The method 10 and the method 20 include the following operations. In an operation 11 of the method 10 and an operation 21 of the method 20, a photoresist layer 103 on a target layer 101 is patterned to form a first opening 104 in a patterned photoresist layer 105. In an operation 12 of the method 10 and an operation 22 of the method 20, a directed self-assembly layer 106 is formed on the patterned photoresist layer 105 and in the first opening 104. In the operation 12 of the method 10, a directed self-assembly material in the directed self-assembly layer 106 separates into a first phase 106A on the patterned photoresist layer 105 and a second phase 106B in the first opening 104 by the first phase 106A being attracted by a polarity of the patterned photoresist layer 105. However, in the operation 22 of the method 20, a directed self-assembly material in the directed self-assembly layer 106 separates into a first phase 106A and a second phase 106B by the first phase 106A being attracted by a water affinity of the patterned photoresist layer 105, the first phase 106A covers a top surface of the patterned photoresist layer 105 and a side surface of the first opening 104, and the second phase 106B is surrounded by the first phase 106A. In an operation 13 of the method 10 and an operation 23 of the method 20, the second phase 106B is removed to form a second opening 107 through the first phase 106A of the directed self-assembly layer 106. In an operation 14 of the method 10 and an operation 24 of the method 20, the target layer 101 is etched through the second opening 107.

The present disclosure uses the combination of the patterned photoresist layer 105 and the first phase 106A of the directed self-assembly layer 106 to pattern the target layer 101. Therefore, compared with using only the patterned photoresist layer 105 to pattern the target layer 101, the photoresist layer 103 of the present disclosure can be thinner to prevent the standing wave of the light from staying in the photoresist layer 103 to change the expected pattern of the first opening 104 when patterning the photoresist layer 103 in the operation 11 and the operation 21 to form the first opening 104. Once the first opening 104 meets the expectation, for example, without increasing the roughness, without causing footing or undercut, and so on, the second opening 107 formed in the operation 13 and the operation 23 by removing the second phase 106B of the directed self-assembly layer 106 in the first opening 104 may also have the same high quality as the first opening 104. In addition to the high quality of the second opening 107, the thickness of the mask used in the operation 14 and the operation 24 to etch the target layer 101 includes the contributions from both the patterned photoresist layer 105 and the first phase 106A of the directed self-assembly layer 106, so the mask can be thick enough to form the pattern with a higher aspect ratio in the target layer 101. Overall, the pattern formed in the target layer 101 has high quality, for example, reducing the roughness to improve the line edge roughness (LER) and/or the line width roughness (LWR), reducing footing or undercut, and so on, and the pattern in the target layer 101 can have a higher aspect ratio. Next, the method 10 and the method 20 of the present disclosure are described in detail with the following embodiments.

See FIG. 3. Before patterning the photoresist layer 103 in the operation 11 and the operation 21, in some embodiments, the method 10 and the method 20 may further include forming a hard mask layer 102 on the target layer 101 and forming the photoresist layer 103 on the hard mask layer 102. The target layer 101 may be any layer to be etched in the following operations. The photoresist layer 103 will be patterned to form the patterned photoresist layer 105 used in the following operations as the mask to etch the target layer 101. The hard mask layer 102 can also be used as the mask similar to the patterned photoresist layer 105 in the following operations to etch the target layer 101, in which the pattern (e.g., the second opening 107) formed in the patterned photoresist layer 105 can be transferred to the hard mask layer 102 when etching the target layer 101. Compared with excluding the hard mask layer 102, since the etch resistance of the hard mask layer 102 is larger than the etch resistance of the photoresist layer 103, when transferring the pattern into the target layer 101, the size of the pattern remains the same more easily. In some embodiments, the hard mask layer 102 includes any suitable hard mask material, for example, including amorphous carbon, silicon nitride, or a combination thereof. In some embodiments, the hard mask layer 102 is a neutral layer that has no preference for the alignment of the directed self-assembly material in the directed self-assembly layer 106. In some embodiments, forming the hard mask layer 102 and forming the photoresist layer 103 are performed by any suitable method, for example, by a chemical vapor deposition or a physical vapor deposition.

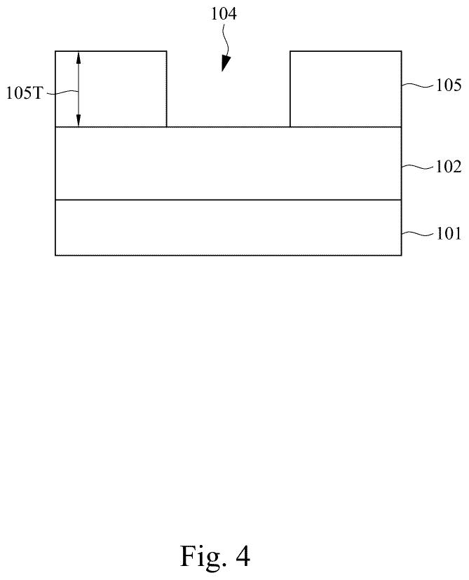

See FIG. 4. In the operation 11 and the operation 21, the photoresist layer 103 on the target layer 101 is patterned to form the first opening 104 in the formed patterned photoresist layer 105 by any suitable photolithography method. Since the patterned photoresist layer 105 will be used with the first phase 106A of the directed self-assembly layer 106 as the mask in the following operations to etch the target layer 101, the thickness 103T of the photoresist layer 103 can be thinner. In some embodiments, the thickness 103T of the photoresist layer 103 is preferably from 80 nm to 120 nm, for example, 80 nm, 90 nm, 100 nm, 110 nm, or 120 nm. When the thickness 103T is too large, the quality of the first opening 104 may drop as described above, and when the thickness 103T is too small, the mask used in the following operations to etch the target layer 101 may be not suitable for forming the pattern with a higher aspect ratio in the target layer 101. In some embodiments, the thickness 105T of the patterned photoresist layer 105 is preferably from 80 nm to 120 nm, for example, 80 nm, 90 nm, 100 nm, 110 nm, or 120 nm. In some embodiments, the thickness 103T of the photoresist layer 103 and the thickness 105T of the patterned photoresist layer 105 are substantially the same. In some embodiments, the first opening 104 penetrates the patterned photoresist layer 105 to extend from the upper surface of the patterned photoresist layer 105 to the lower surface of the patterned photoresist layer 105. In some embodiments, the first opening 104 exposes the layer (e.g., the target layer 101 or the hard mask layer 102) below the patterned photoresist layer 105.

In some embodiments, the photoresist layer 103 (or the patterned photoresist layer 105) includes any suitable photoresist material, for example, including polymethylmethacrylate, epoxy-based polymer, or the like. In some embodiments, the material of the photoresist layer 103 (or the patterned photoresist layer 105) is polar, such that the patterned photoresist layer 105 may attract the polar end of the first phase 106A of the directed self-assembly layer 106 when the directed self-assembly layer 106 is formed on the patterned photoresist layer 105 in the following operations. In some embodiments, the material of the photoresist layer 103 (or the patterned photoresist layer 105) is nonpolar, such that the patterned photoresist layer 105 may attract the nonpolar end of the first phase 106A of the directed self-assembly layer 106 when the directed self-assembly layer 106 is formed on the patterned photoresist layer 105 in the following operations. In some embodiments, the material of the photoresist layer 103 (or the patterned photoresist layer 105) is hydrophilic, such that the patterned photoresist layer 105 may attract the hydrophilic end of the first phase 106A of the directed self-assembly layer 106 when the directed self-assembly layer 106 is formed on the patterned photoresist layer 105 in the following operations. In some embodiments, the material of the photoresist layer 103 (or the patterned photoresist layer 105) is hydrophobic, such that the patterned photoresist layer 105 may attract the hydrophobic end of the first phase 106A of the directed self-assembly layer 106 when the directed self-assembly layer 106 is formed on the patterned photoresist layer 105 in the following operations.

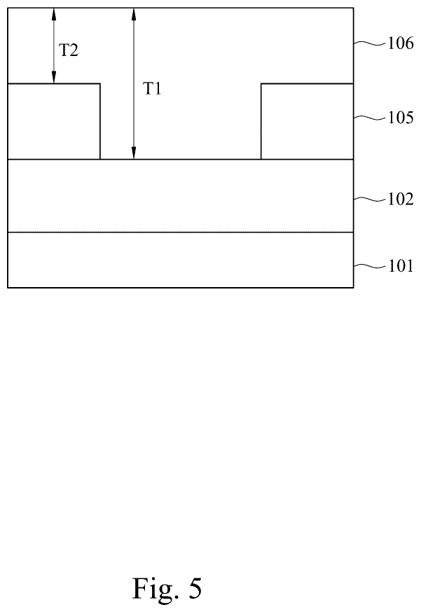

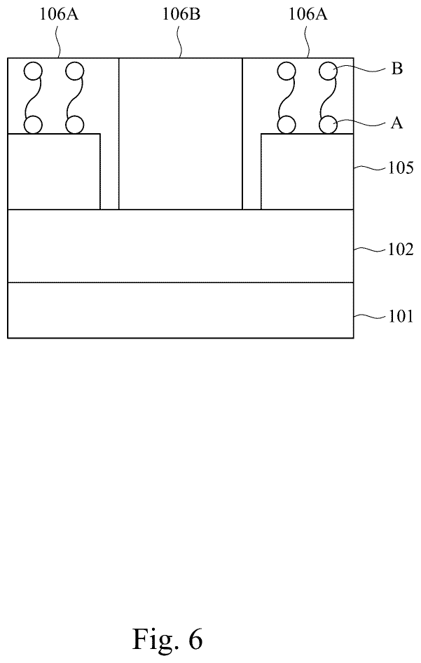

See FIGS. 5 and 6. In the operation 12 and the operation 22, the directed self-assembly layer 106 is formed on the patterned photoresist layer 105 and the first opening 104 by any suitable deposition method, for example, by a chemical vapor deposition or a physical vapor deposition. The directed self-assembly material in the directed self-assembly layer 106 may self-assemble into different phases (e.g., the first phase 106A and the second phase 106B) based on the environments where the directed self-assembly layer 106 is disposed on. For example, the patterned photoresist layer 105 and the first opening 104 may provide different environments (e.g., different surface shapes, different surface properties, and so on) to the directed self-assembly layer 106, such that the directed self-assembly material on the patterned photoresist layer 105 forms the first phase 106A, and the directed self-assembly material on the first opening 104 forms the second phase 106B. By reassembling the directed self-assembly material of the directed self-assembly layer 106 into the first phase 106A and the second phase 106B based on the positions of the patterned photoresist layer 105 and the first opening 104, the first phase 106A can be selectively remained on the patterned photoresist layer 105 to increase the total thickness of the mask used in the following operations, and the second phase 106B can be selectively removed to form the second opening 107 used in the following operations to etch the target layer 101. For example, in some embodiments, in the operation 12 and the operation 22, a total thickness T1 of the patterned photoresist layer 105 and a portion of the directed self-assembly layer 106 on the patterned photoresist layer 105 is preferably from 120 nm to 300 nm, for example, 120 nm, 150 nm, 200 nm, 225 nm, 250 nm, 275 nm, or 300 nm, so the mask used in the following operations to etch the target layer 101 may not be too thin to fail to form a pattern with a higher aspect ratio in the target layer 101 and may not be too thick to cause unnecessary waste without a benefit. In some embodiments, in the operation 12 and the operation 22, a thickness T2 of a portion of the directed self-assembly layer 106 on the patterned photoresist layer 105 is preferably from 10 nm to 180 nm, for example, 10 nm, 25 nm, 50 nm, 75 nm, 100 nm, 125 nm, 150 nm, or 180 nm. In some embodiments, the first phase 106A further includes a portion extending to cover the side surface of the patterned photoresist layer 105. In some embodiments, the first phase 106A covers a side surface of the first opening 104. In some embodiments, the second phase 106B is surrounded by the first phase 106A and separated from the patterned photoresist layer 105. In some embodiments, the directed self-assembly layer 106 contacts the patterned photoresist layer 105 and the layer (e.g., the target layer 101 or the hard mask layer 102) exposed by the first opening 104.

In some embodiments, the directed self-assembly material in the directed self-assembly layer 106 includes a first end A and a second end B, in which the patterned photoresist layer 105 attracts the first end A to attach to the patterned photoresist layer 105 and repels the second end B to be close to the patterned photoresist layer 105, such that the directed self-assembly material separates into the first phase 106A and the second phase 106B aligned differently on the patterned photoresist layer 105 and the first opening 104.

In some embodiments, the directed self-assembly material in the directed self-assembly layer 106 separates into the first phase 106A and the second phase 106B by the first phase 106A being attracted by the polarity of the patterned photoresist layer 105. For example, in some embodiments of the operation 12, the first end A of the directed self-assembly material is a polar end and the second end B of the directed self-assembly material is a nonpolar end, and the patterned photoresist layer 105 is polar to attract the polar end of the directed self-assembly material in the first phase 106A. For example, in some embodiments of the operation 12, the first end A of the directed self-assembly material is a nonpolar end and the second end B of the directed self-assembly material is a polar end, and the patterned photoresist layer 105 is nonpolar to attract the nonpolar end of the directed self-assembly material in the first phase 106A. In some embodiments, a dipole moment of the polar end is larger than a dipole moment of the nonpolar end. In some embodiments, a difference between a dipole moment of the first end A of the directed self-assembly material attached to the patterned photoresist layer 105 and a dipole moment of the material of the patterned photoresist layer 105 is smaller than a difference between a dipole moment of the second end B of the directed self-assembly material and the dipole moment of the material of the patterned photoresist layer 105. In some embodiments, the polar end includes vinylpyridine, isoprene, methyl methacrylate, ethylene oxide, tetrahydrofuran, oxetane, or combinations thereof. In some embodiments, the nonpolar end includes styrene, isoprene, caprolactone, or combinations thereof. In some embodiments, the directed self-assembly material is a copolymer including the following monomers, for example, a copolymer including styrene and vinylpyridine (e.g., poly(styrene-b-vinylpyridine)); a copolymer including styrene and isoprene (e.g., poly(styrene-b-isoprene)); a copolymer including styrene and methyl methacrylate (e.g., poly(styrene-b-methyl methacrylate)); a copolymer including isoprene and ethylene oxide (e.g., poly(isoprene-b-ethylene oxide)); a copolymer including ethylene oxide and caprolactone (e.g., poly(ethylene oxide-b-caprolactone)); a copolymer including styrene and tetrahydrofuran (e.g., poly(styrene-b-tetrahydrofuran)); a copolymer including styrene, isoprene, and ethylene oxide (e.g., poly(styrene-b-isoprene-b-ethylene oxide)); a copolymer including styrene and oxetane (e.g., poly(styrene-b-oxetane)); a copolymer including styrene and dimethylsiloxane (e.g., poly(styrene-b-dimethylsiloxane)); a copolymer including styrene and ethylene oxide (e.g., poly(styrene-b-ethylene oxide)); a copolymer including styrene and actic acid (e.g., poly(styrene-b-actic acid)); a copolymer including styrene and vinyl alcohol (e.g., poly(styrene-b-vinyl alcohol)); or combinations thereof. In some embodiments, the copolymer of the directed self-assembly material aligns vertically on the surface (e.g., the top surface) of the patterned photoresist layer 105.

In some embodiments, the directed self-assembly material in the directed self-assembly layer 106 separates into the first phase 106A and the second phase 106B by the first phase 106A being attracted by the water affinity of the patterned photoresist layer 105. For example, in some embodiments of the operation 22, the first end A of the directed self-assembly material is a hydrophilic end and the second end B of the directed self-assembly material is a hydrophobic end, and the patterned photoresist layer 105 is hydrophilic to attract the hydrophilic end of the directed self-assembly material in the first phase 106A. For example, in some embodiments of the operation 22, the first end A of the directed self-assembly material is a hydrophobic end and the second end B of the directed self-assembly material is a hydrophilic end, and the patterned photoresist layer 105 is hydrophobic to attract the hydrophobic end of the directed self-assembly material in the first phase 106A. In some embodiments, a water solubility of the hydrophilic end is larger than a water solubility of the hydrophobic end. In some embodiments, a difference between a water solubility of the first end A of the directed self-assembly material attached to the patterned photoresist layer 105 and a water solubility of the material of the patterned photoresist layer 105 is smaller than a difference between a water solubility of the second end B of the directed self-assembly material and the water solubility of the material of the patterned photoresist layer 105. In some embodiments, the hydrophilic end includes vinylpyridine, isoprene, methyl methacrylate, ethylene oxide, tetrahydrofuran, butadiene, or combinations thereof. In some embodiments, the hydrophobic end includes styrene, isoprene, caprolactone, butadiene, (trimethylsilyl)methyl methacrylate, propylene oxide, or combinations thereof. In some embodiments, the directed self-assembly material is a copolymer including the following monomers, for example, a copolymer including styrene and vinylpyridine (e.g., poly(styrene-b-vinylpyridine)); a copolymer including styrene and isoprene (e.g., poly(styrene-b-isoprene)); a copolymer including styrene and methyl methacrylate (e.g., poly(styrene-b-methyl methacrylate)); a copolymer including isoprene and ethylene oxide (e.g., poly(isoprene-b-ethylene oxide)); a copolymer including ethylene oxide and caprolactone (e.g., poly(ethylene oxide-b-caprolactone)); a copolymer including styrene and tetrahydrofuran (e.g., poly(styrene-b-tetrahydrofuran)); a copolymer including styrene, isoprene, and ethylene oxide (e.g., poly(styrene-b-isoprene-b-ethylene oxide)); a copolymer including styrene and butadiene (e.g., poly(styrene-b-butadiene)); a copolymer including butadiene and ethylene oxide (e.g., poly(butadiene-b-ethylene oxide)); a copolymer including methyl methacrylate and (trimethylsilyl)methyl methacrylate (e.g., poly(methyl methacrylate-b-(trimethylsilyl)methyl methacrylate)); a copolymer including ethylene oxide and propylene oxide (e.g., poly(ethylene oxide-b-propylene oxide)); a copolymer including styrene and dimethylsiloxane (e.g., poly(styrene-b-dimethylsiloxane)); a copolymer including styrene and ethylene oxide (e.g., poly(styrene-b-ethylene oxide)); a copolymer including styrene and actic acid (e.g., poly(styrene-b-actic acid)); a copolymer including styrene and vinyl alcohol (e.g., poly(styrene-b-vinyl alcohol)); or combinations thereof. In some embodiments, the copolymer of the directed self-assembly material aligns vertically on the surface (e.g., the top surface) of the patterned photoresist layer 105.

In some embodiments, the directed self-assembly material includes a first moiety (e.g., a monomer described above in the copolymer of the directed self-assembly material) having a first glass transition temperature and a second moiety (e.g., another monomer described above in the copolymer of the directed self-assembly material) having a second glass transition temperature smaller than the first glass transition temperature, and when the directed self-assembly material separates into the first phase 106A and the second phase 106B, the first moiety is the first end A attached to the patterned photoresist layer 105 and the second moiety is the second end B. In some embodiments, the directed self-assembly layer 106 is formed at a temperature between the first glass transition temperature and the second glass transition temperature, such that the second phase 106B is softer to be removed more easily in the following operations than the first phase 106A. In some embodiments, the first glass transition temperature is from 120° C. to 150° C., for example, 120° C., 125° C., 130° C., 135° C., 140° C., 145° C., or 150° C. In some embodiments, the second glass transition temperature is from 85° C. to 115° C., for example, 85° C., 90° C., 95° C., 100° C., 105° C., 110° C., or 115° C.

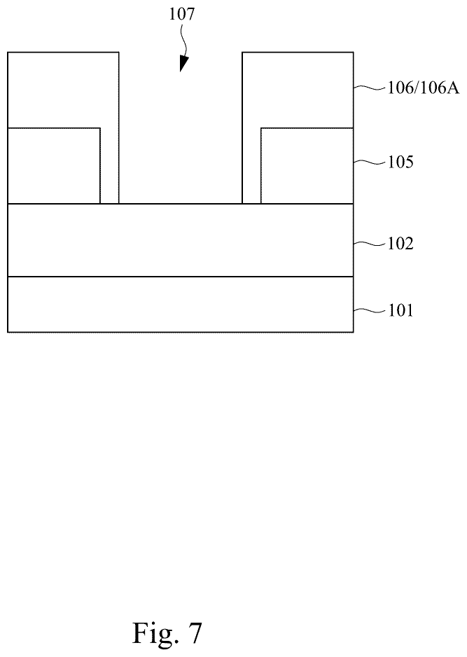

See FIG. 7. In the operation 13 and the operation 23, the second phase 106B of the directed self-assembly layer 106 is removed by any suitable etching method, for example, by a dry etching method or a wet etching method, to form the second opening 107 in the patterned photoresist layer 105 and the first phase 106A of the directed self-assembly layer 106. The patterned photoresist layer 105 and the first phase 106A of the directed self-assembly layer 106 will be used as the mask to etch the target layer 101 in the following operations, and the second opening 107 defines where the pattern is formed in the target layer 101.

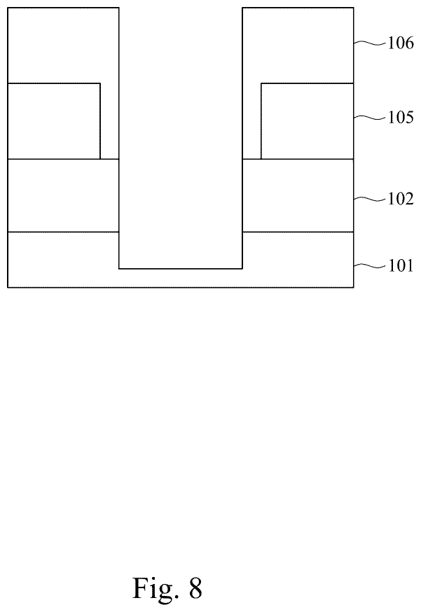

See FIG. 8. In the operation 14 and the operation 24, the target layer 101 is etched through the second opening 107 by any suitable etching method, for example, by a dry etching method or a wet etching method. In the embodiments including the hard mask layer 102, the hard mask layer 102 is etched through the second opening 107 before etching the target layer 101.

The methods of the present disclosure use the combination of the photoresist material and the directed self-assembly material to pattern the target layer, so the layer of the photoresist material can be thinner to prevent the standing wave of the light from staying in the layer of the photoresist material to affect the pattern formed in the layer of the photoresist material when patterning the layer of the photoresist material. Therefore, the pattern in the layer of the photoresist material can be formed as expected and transferred into the layer of the directed self-assembly material, and when using the patterned layers of the photoresist material and the directed self-assembly material to etch the target layer, the pattern formed in the target layer also meets the expectation, for example, having a higher resolution, having a higher aspect ratio, reducing the roughness to improve the line edge roughness (LER) and/or the line width roughness (LWR), reducing footing or undercut, and so on.

The present disclosure is described in considerable detail in some embodiments, but other embodiments may also be feasible, so the description of the embodiments in the present disclosure is not intended to limit the scope and spirit of the claims attached. For one skilled in the art, the present disclosure may be modified and changed without deviating from the scope and spirit of the present disclosure. Such modifications and changes are intended to be covered by the present disclosure when they belong to the scope and spirit of the attached claims.

What is claimed is:

1. A method of forming a patterned structure, comprising:
patterning a photoresist layer on a target layer to form a first opening in a patterned photoresist layer;
forming a directed self-assembly layer on the patterned photoresist layer and in the first opening, wherein a directed self-assembly material in the directed self-assembly layer separates into a first phase on the patterned photoresist layer and a second phase in the first opening by the first phase being attracted by a polarity of the patterned photoresist layer;
removing the second phase to form a second opening through the directed self-assembly layer; and
etching the target layer through the second opening.

2. The method of claim 1, wherein a thickness of the photoresist layer is from 80 nm to 120 nm.

3. The method of claim 1, wherein when forming the directed self-assembly layer on the patterned photoresist layer, a total thickness of the patterned photoresist layer and a portion of the directed self-assembly layer on the patterned photoresist layer is from 120 nm to 300 nm.

4. The method of claim 1, wherein when forming the directed self-assembly layer on the patterned photoresist layer, a thickness of a portion of the directed self-assembly layer on the patterned photoresist layer is from 10 nm to 180 nm.

5. The method of claim 1, wherein the patterned photoresist layer is polar to attract a polar end of the first phase, or the patterned photoresist layer is nonpolar to attract a nonpolar end of the first phase.

6. The method of claim 1, wherein the directed self-assembly material comprises a first moiety having a first glass transition temperature and a second moiety having a second glass transition temperature smaller than the first glass transition temperature, and the first moiety is attached to the patterned photoresist layer when the directed self-assembly material separates into the first phase and the second phase.

7. The method of claim 6, wherein the directed self-assembly layer is formed at a temperature between the first glass transition temperature and the second glass transition temperature.

8. The method of claim 1, wherein the directed self-assembly material is a copolymer, and the copolymer aligns vertically on a surface of the patterned photoresist layer.

9. The method of claim 1, wherein the first phase further comprises a portion extending to cover a side surface of the patterned photoresist layer.

10. The method of claim 1, further comprising forming a hard mask layer on the target layer and forming the photoresist layer on the hard mask layer before patterning the photoresist layer.

11. A method of forming a patterned structure, comprising:
patterning a photoresist layer on a target layer to form a first opening in a patterned photoresist layer;
forming a directed self-assembly layer on the patterned photoresist layer and in the first opening, wherein a directed self-assembly material in the directed self-assembly layer separates into a first phase and a second phase by the first phase being attracted by a water affinity of the patterned photoresist layer, the first phase covers a top surface of the patterned photoresist layer and a side surface of the first opening, and the second phase is surrounded by the first phase;
removing the second phase to form a second opening through the directed self-assembly layer; and
etching the target layer through the second opening.

12. The method of claim 11, wherein a thickness of the photoresist layer is from 80 nm to 120 nm.

13. The method of claim 11, wherein when forming the directed self-assembly layer on the patterned photoresist layer, a total thickness of the patterned photoresist layer and a portion of the directed self-assembly layer on the patterned photoresist layer is from 120 nm to 300 nm.

14. The method of claim 11, wherein when forming the directed self-assembly layer on the patterned photoresist layer, a thickness of a portion of the directed self-assembly layer on the patterned photoresist layer is from 10 nm to 180 nm.

15. The method of claim 11, wherein the patterned photoresist layer is hydrophilic to attract a hydrophilic end of the first phase, or the patterned photoresist layer is hydrophobic to attract a hydrophobic end of the first phase.

16. The method of claim 11, wherein the directed self-assembly material comprises a first moiety having a first glass transition temperature and a second moiety having a second glass transition temperature smaller than the first glass transition temperature, and the first moiety is attached to the patterned photoresist layer when the directed self-assembly material separates into the first phase and the second phase.

17. The method of claim 16, wherein the directed self-assembly layer is formed at a temperature between the first glass transition temperature and the second glass transition temperature.

18. The method of claim 11, wherein the directed self-assembly material is a copolymer, and the copolymer aligns vertically on the top surface of the patterned photoresist layer.

19. The method of claim 11, further comprising forming a hard mask layer on the target layer and forming the photoresist layer on the hard mask layer before patterning the photoresist layer.
